(19) United States
(12) Patent Application Publication
(10) Pub. No.: US 2017/0069660 A1
(43) Pub. Date: Mar. 9, 2017

(54) CELL STRUCTURE IN INTERGRATED CIRCUITS FOR ECO AT UPPER METAL LAYER AND METHOD FOR FORMING SPARE CELL STRUCTURE

(71) Applicant: SAMSUNG ELECTRONICS CO., LTD., Suwon-si (KR)

(72) Inventor: Hyun-Teck OH, Suwon-si (KR)

(73) Assignee: SAMSUNG ELECTRONICS CO., LTD., Suwon-si (KR)

(21) Appl. No.: 15/255,524

(22) Filed: Sep. 2, 2016

(30) Foreign Application Priority Data
Sep. 4, 2015 (KR) 10-2015-0125712

(51) Int. Cl. H01L 27/118; H01L 21/8238

(52) U.S. Cl. CPC H01L 27/11807; H01L 21/823871; H01L 2027/1182; H01L 2027/11827; H01L 2027/11874; H01L 2027/11888

(57) ABSTRACT

An integrated circuit includes a functional cell, and a spare gate cell configured to change or add a function of the functional cell in response to an engineering change order (ECO). The spare gate cell includes transistors configured as a decoupling capacitor before the ECO, and the spare gate cell is configured to change into an ECO cell including an interconnection metal line pattern disposed in the decoupling capacitor after the ECO.

### CROSS-REFERENCE TO RELATED APPLICATIONS

This application claims priority from Korean Patent Application No. 10-2015-0125712, filed on Sep. 4, 2015, in the Korean Intellectual Property Office, the disclosure of which is herein incorporated by reference in its entirety.

### BACKGROUND

1. Field

Apparatuses and methods consistent with example embodiments relate to integrated circuits (ICs) and, more particularly, to a spare cell formed for an engineering change order (ECO) when a functional cell is formed in an integrated circuit (IC).

2. Description of the Related Art

An integrated circuit is manufactured by performing processes such as deposition, masking, and etching.

An integrated circuit may include electronic components each including a plurality of functional cells to perform a set function. In addition, the integrated circuit may include a few spare cells to revise or add functions other than the functional cells. The spare cells do not play an active role while the integrated circuit operates.

While spare cells may be designed to revise or add functions, they are not connected to electronic components that normally function according to an original circuit design of an integrated circuit. As a result, some of the spare cells may be selectively connected to the normally functioning electronic components during a revising or routing process of the IC. This process is often referred to as an engineering change order (hereinafter referred to as “ECO”), and the spare cell is often referred to as an ECO cell.

Because spare cells for forming ECO cells may be implemented with logic gates such as an inverter, a NAND gate, and a NOR gate, they are also often referred to spare gate cells.

Chip designers of an integrated circuit use a spare gate cell as an ECO cell to change or revise a function or timing of a function cell.

### SUMMARY

One or more example embodiments provide a spare gate cell of an integrated circuit and a method for forming a spare gate cell structure.

According to example embodiments, there is provided an integrated circuit including a functional cell, and a spare gate cell configured to change or add a function of the functional cell in response to an engineering change order (ECO). The spare gate cell includes transistors configured as a decoupling capacitor before the ECO, and the spare gate cell is configured to change into an ECO cell including an interconnection metal line pattern disposed in the decoupling capacitor after the ECO.

The transistors may include first group transistors having a first conductivity type, and second group transistors having a second conductivity type. The spare gate cell may further include a first interconnection line connected to a source or a drain of each of two or more of the first group transistors, a second interconnection line connected to a source or a drain of each of two or more of the second group transistors, and a third interconnection line connected to gates of two or more of the first group transistors and the second group transistors.

The ECO cell may further include an input connected to the third interconnection line, and an output connected to the interconnection metal line pattern.

The interconnection metal line pattern may be formed in an upper process higher than a metal-1 process, in response to the ECO.

The upper process may include a metal-2 process.

The upper process may include a metal-3 process.

The ECO cell may be configured as an inverter circuit.

The ECO cell may be configured as a NAND circuit.

The ECO cell may be configured as a NOR circuit.

The transistors may include eight complementary metal oxide semiconductor transistors.

According to exemplary embodiments, there is provided a method for forming a spare cell structure of an integrated circuit, the method including forming, in the integrated circuit, a spare gate cell as a decoupling capacitor before an engineering change order (ECO), and forming an interconnection metal line pattern in the decoupling capacitor after the ECO event to change the spare gate cell into an ECO cell.

The method may further include forming a functional cell in the integrated circuit.

The spare gate cell may include first group transistors having a first conductivity type, second group transistors having a second conductivity type, a first interconnection line connected to a source or a drain of each of two or more of the first group transistors, a second interconnection line connected to a source or a drain of each of two or more of the second group transistors, and a third interconnection line connected to gates of two or more of the first group transistors and the second group transistors.

The interconnection metal line pattern may be formed in an upper process higher than a metal-1 process, in response to the ECO.

The ECO cell may be configured as one among an inverter circuit, a NAND circuit, and a NOR circuit.

According to example embodiments, an integrated circuit includes a functional cell, and a spare gate cell configured to change or add a function of the functional cell in response to an engineering change order (ECO). Before the ECO, the spare gate cell includes first transistors having a first conductivity type, second transistors having a second conductivity type, a first interconnection line connected to a source or a drain of each of two or more of the first transistors, a second interconnection line connected to a source or a drain of each of two or more of the second transistors, and a third interconnection line connected to gates of the first group transistors and the second group transistors. After the ECO, the spare gate cell further includes a fourth interconnection line connected to the first interconnection line and the second interconnection line.

After the ECO, the spare gate cell may further include an input connected to the third interconnection line, and an output connected to the fourth interconnection line.

The spare gate cell may further include the fourth interconnection line after the ECO and after forming a metal layer over the first transistors and second transistors.

The first transistors may include a first PMOS transistor, a second PMOS transistor including a source connected to a drain of the first PMOS transistor, a third PMOS transistor including a source connected to the source of the second PMOS transistor via the first interconnection line, and a fourth PMOS transistor including a source connected to the source of the third PMOS transistor. The second transistors may include a first NMOS transistor, a second NMOS transistor including a drain connected to a source of the first NMOS transistor, a third NMOS transistor including a drain connected to the drain of the second NMOS transistor via the second interconnection line, and a fourth NMOS transistor including a drain connected to the drain of the third NMOS transistor.

The first transistors may include a first PMOS transistor, a second PMOS transistor including a source connected to a drain of the first PMOS transistor, a third PMOS transistor including a source connected to the source of the second PMOS transistor via the first interconnection line, and a fourth PMOS transistor including a source connected to the source of the third PMOS transistor. The second transistors may include a first NMOS transistor, a second NMOS transistor including a drain connected to a source of the first NMOS transistor, a third NMOS transistor including a source connected to a source of the second NMOS transistor via the second interconnection line, and a fourth NMOS transistor including a drain connected to the drain of the third NMOS transistor. The third interconnection line may include a first line connected to gates of the first PMOS transistor, the first NMOS transistor, the fourth PMOS transistor, and the fourth NMOS transistor, and a second line connected to the second PMOS transistor, the second NMOS transistor, the third PMOS transistor, and the third NMOS transistor.

### BRIEF DESCRIPTION OF THE DRAWINGS

The above and/or other aspects will be more apparent by describing example embodiments with reference to the accompanying drawings in which:

FIG. 1 is a block diagram illustrating an IC according to example embodiments;

FIG. 2 is a diagram illustrating an example of changing or revising a spare gate cell into an ECO cell, according to example embodiments;

FIG. 3 is a flowchart illustrating a method of forming an ECO cell at an upper metal layer, according to example embodiments;

FIG. 4 is a circuit diagram illustrating a decoupling capacitor circuit capable of changing into an inverter, according to example embodiments;

FIG. 5 is a circuit diagram illustrating an example of forming an ECO cell using the decoupling capacitor circuit in FIG. 4 during an ECO event;

FIG. 6 is a diagram illustrating a layout of the decoupling capacitor circuit according to FIG. 4;

FIG. 7 is a diagram illustrating a layout of an ECO cell using the decoupling capacitor circuit according to FIG. 5;

FIG. 8 is a circuit diagram illustrating a decoupling capacitor circuit capable of changing into a NAND circuit, according to example embodiments;

FIG. 9 is a circuit diagram illustrating an example of forming an ECO cell for a NAND function using the decoupling capacitor circuit in FIG. 8 during an ECO event;

FIG. 10 is a diagram illustrating a layout of the decoupling capacitor circuit according to FIG. 8;

FIG. 11 is a diagram illustrating a layout of an ECO cell for a NAND function using the decoupling capacitor circuit according to FIG. 9;

FIG. 12 is a diagram illustrating a vertical structure of a MOS transistor, according to example embodiments;

FIG. 13 is a block diagram illustrating an application example applied to a computing device; and

FIG. 14 is a block diagram illustrating an application example applied to a cloud system.

### DETAILED DESCRIPTION

The advantages and features of example embodiments and methods of achieving them will be apparent from the following example embodiments that will be described in more detail with reference to the accompanying drawings. It may be noted, however, that the example embodiments are not limited to the following example embodiments, and may be implemented in various forms. Accordingly, the example embodiments are provided only to let those skilled in the art know the concept of the example embodiments.

The drawings may be modified by manufacturing techniques and/or tolerances. Accordingly, the example embodiments are not limited to configurations shown in the drawings, and include modifications based on the method of manufacturing the semiconductor device. Regions or areas shown in the drawings have schematic characteristics. In addition, the shapes of the regions shown in the drawings exemplify shapes of regions in an element, and do not limit the example embodiments. Though terms like a first, a second, and a third are used to describe various elements in one or more example embodiments, the elements are not limited to these terms. These terms are used only to tell one element from another element. An example embodiment described and exemplified herein includes a complementary example embodiment thereof.

The terms used in the example embodiments are for the purpose of describing example embodiments only and are not intended to be limiting of the example embodiments. As used in the specification, the singular forms “a”, “an” and “the” are intended to include the plural forms as well, unless the context clearly indicates otherwise. It will be further understood that the terms “comprises” and/or “comprising”, when used in the example embodiments, specify the presence of stated features, integers, steps, operations, elements, and/or components, but do not preclude the presence or addition of one or more other features, integers, steps, operations, elements, components, and/or groups thereof.

Hereinafter, example embodiments will now be described more fully with reference to accompanying drawings.

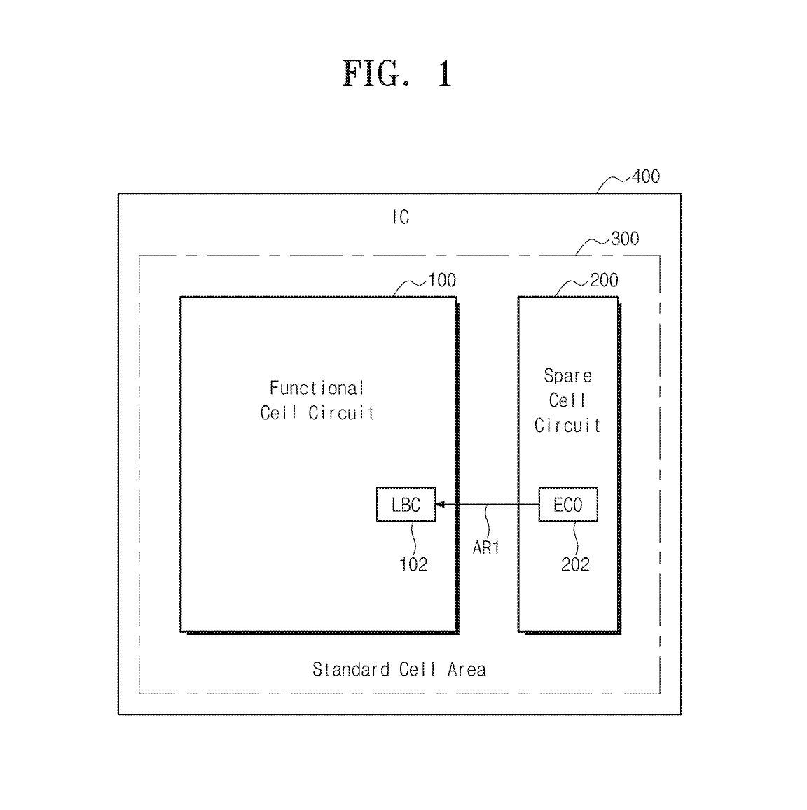

FIG. 1 is a block diagram illustrating an IC 400 according to example embodiments. As illustrated, the IC 400 has a standard cell area 300 including a functional cell circuit 100 and a spare cell circuit 200.

The spare cell circuit 200 includes spare gate cells. Because the spare gate cells are not connected to electronic components that normally function in the functional cell circuit 100 before the spare gate cells change into ECO cells, they are not activated during operation of an integrated circuit.

As a result, a spare gate cell of the spare cell circuit 200 in the standard cell area 300 changes into an ECO cell 202 when an ECO event occurs. The ECO cell 202 may be rerouted to the functional cell circuit 100 to change, revise or add a function or timing of functional cells, as indicated by an arrow AR1.

In example embodiments, a spare gate cell that is a cell before changing into the ECO cell 202 may be formed in the type of a decoupling capacitor such that an ECO is implemented by the spare gate cell.

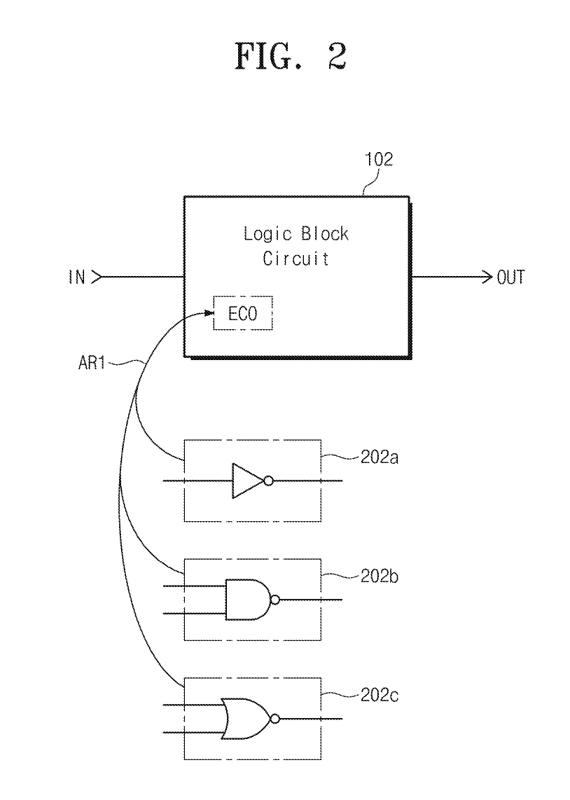

FIG. 2 is a diagram illustrating an example of changing or revising a spare gate cell into an ECO cell, according to example embodiments. As indicated by arrows AR1 in FIG. 2, various cells changing into ECO cells from spare gate cells are connected to functional cells that are electronic components in a logic block circuit (LBC) 102.

For example, when an electronic component in the LBC 102 is a buffer circuit and delay time of the buffer circuit is shorter than designed delay time, delay time of the buffer circuit may be increased. If a selected one of the spare gate cells changes into an ECO cell 202a having an inverter function and the ECO cell 202a is rerouted to a buffer circuit, the delay time of the buffer circuit increases.

Similarly, when an ECO cell 202b having a NAND gate function is connected to an electronic component in the LBC 102, a NAND function may be added, or an originally designed function of the electronic component may change into another function.

In addition, when an ECO cell 202c having a NOR gate function is connected to an electronic component in the LBC 102, a NOR function may be added, or an originally designed function of the electronic device may change into another function.

Although described more fully later in example embodiments, a spare gate cell that is a cell before changing into an ECO cell is fabricated in the type of a decoupling capacitor such that an ECO is implemented even when a process of metal-1 or higher level is performed.

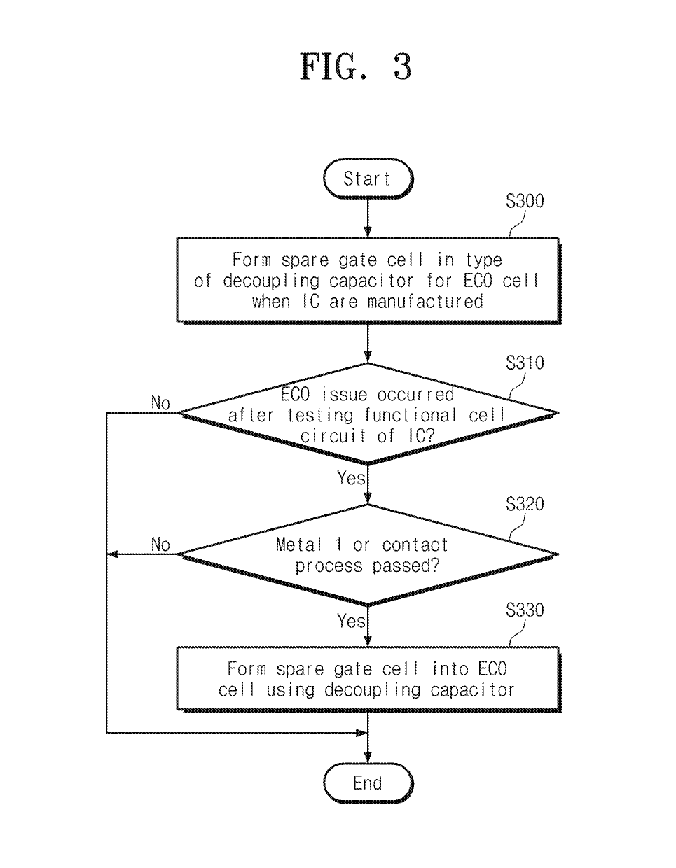

FIG. 3 is a flowchart illustrating a method of forming an ECO cell at an upper metal layer, according to example embodiments.

At S300, a spare gate cell is formed in a type of a decoupling capacitor for an ECO cell when an IC is manufactured or fabricated. Spare gate cells are fabricated together when functional cells are fabricated. For example, a spare gate cell may be formed in the type of a decoupling capacitor as a metal-1 process is performed after a polysilicon gate process. The type of the decoupling capacitor may mean that an overlying gate layer and an underlying source/drain layer constitute a decoupling capacitor structure with a gate insulating layer interposed between the overlying gate layer and the underlying source/drain layer by connecting a source and a drain of a MOS transistor to each other. The polysilicon gate process refers to a process in which a gate of the MOS transistor is formed of polysilicon.

At S310, it is determined whether an ECO event or an ECO issue occurred after testing a functional cell circuit of the IC. When a function or timing of an electronic component is within a designed margin in a test, the ECO event or the ECO issue does not occur. In this case, the spare gate cell does not change into an ECO cell. When a test result is determined to be failure, a function or timing of fabricated functional cells may be changed or revised, and thus the ECO event or the ECO issue occurs.

When the ECO event or the ECO issue occurred, at S320, it is determined whether the metal-1 process or a contact process is passed. That is, if a current process passes the metal-1 process or the contact process when the ECO event or the ECO issue occurs, an ECO cell is not formed by a conventional technique. That is, in the case of the conventional technique, formation of an ECO cell is targeted to the metal-1 process or the contact process. Therefore, it is impossible or difficult to change or revise a function or timing of functional cells even when, for example, an ECO event or the ECO issue occurs in a metal-2 process. The contact process may refer to a process in which a contact is formed at an interlayer dielectric deposited on a source/drain or a gate of a MOS transistor to achieve electrical connection between a metal and a source/drain of a metal-1 layer or between a metal and a gate of the metal-1 layer.

In example embodiments, because a spare gate cell is formed in the type of a decoupling capacitor, an ECO may be implemented by an ECO cell even when the metal-1 process or the contact process is passed at S320.

When the metal-1 processor or the contact process is passed, at S330, the spare gate cell is formed into an ECO cell using the decoupling capacitor. That is, an interconnection metal line pattern is formed at the spare gate cell formed in the type of the decoupling capacitor through a metal interconnection in an upper processor following the metal-1 process or the contact process to change or revise the spare gate cell into an ECO cell. That is, when the spare gate cell existing in the type of the decoupling capacitor is selected as an ECO cell, the interconnection metal line pattern is formed for transistors constituting the decoupling capacitor. Thus, the spare gate cell existing in the type of the decoupling capacitor changes into an ECO cell having a set function due to formation of the interconnection metal line pattern.

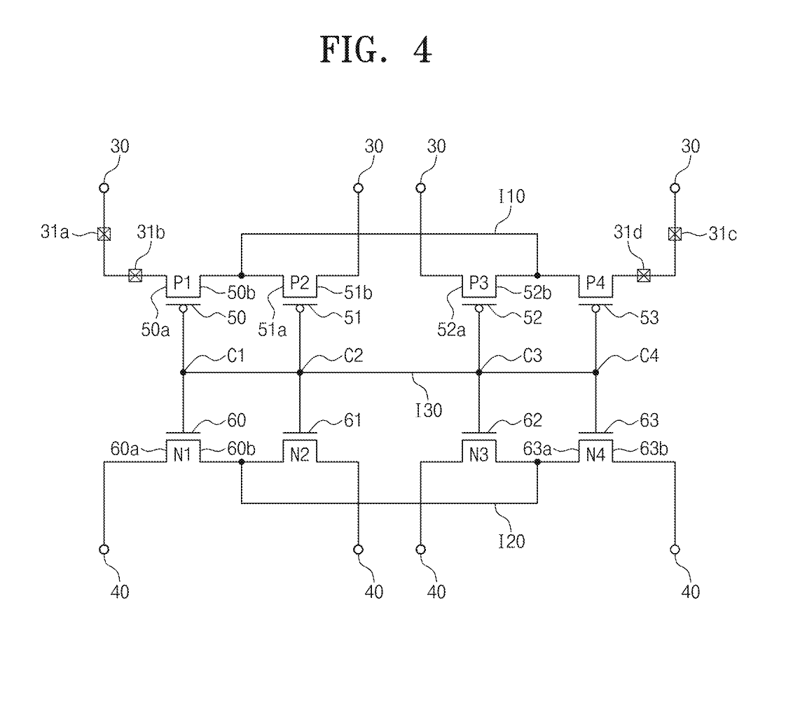

FIG. 4 is a circuit diagram illustrating a decoupling capacitor circuit capable of changing into an inverter, according to example embodiments. As illustrated, the decoupling capacitor circuit includes four PMOS transistors P1, P2, P3, and P4 and four NMOS transistors N1, N2, N3, and N4. For brevity of description, the four PMOS transistors P1, P2, P3, and P4 will be referred to as first-group transistors, and the NMOS transistors N1, N2, N3, and N4 will be referred to as second-group transistors. The four NMOS transistors N1, N2, N3, and N4 and the four PMOS transistors P1, P2, P3, and P4 are CMOS transistors.

A first interconnection line 110 electrically connects a drain 50b of the first PMOS transistor P1 and a source of the fourth PMOS transistor P4. Because the drain 50b of the first PMOS transistor P1 and a source 51a of the second PMOS transistor P2 may be implemented with a common active region, the first interconnection line 110 may also electrically connect the source 51a of the second PMOS transistor P2 and a source 52b of the third PMOS transistor P3.

A second interconnection line 120 electrically connects a source 60b of the first NMOS transistor N1 and a drain 63a of the fourth NMOS transistor N4. Because the source 60b of the first NMOS transistor N1 and a drain of the second NMOS transistor N2 may be implemented with a common active region, the second interconnection line 120 may also electrically connect the drain of the second NMOS transistor N2 and a drain of the third NMOS transistor N3.

A third interconnection line 130 electrically connects a gate of each of the four PMOS transistors P1, P2, P3, and P4 to a gate of each of the four NMOS transistors N1, N2, N3, and N4.

Because the spare gate cell shown in FIG. 4 is formed in the type of a decoupling capacitor to implement an ECO cell, there is no issue of power consumption caused by short-circuit current although a power supply voltage or a ground voltage is not applied to a gate of each of the eight MOS transistors P1, P2, P3, P4, N1, N2, N3, and N4. As a result, a spare gate cell for an ECO cell exists in the form of a decoupling capacitor and may perform a function of an inverter circuit after an ECO.

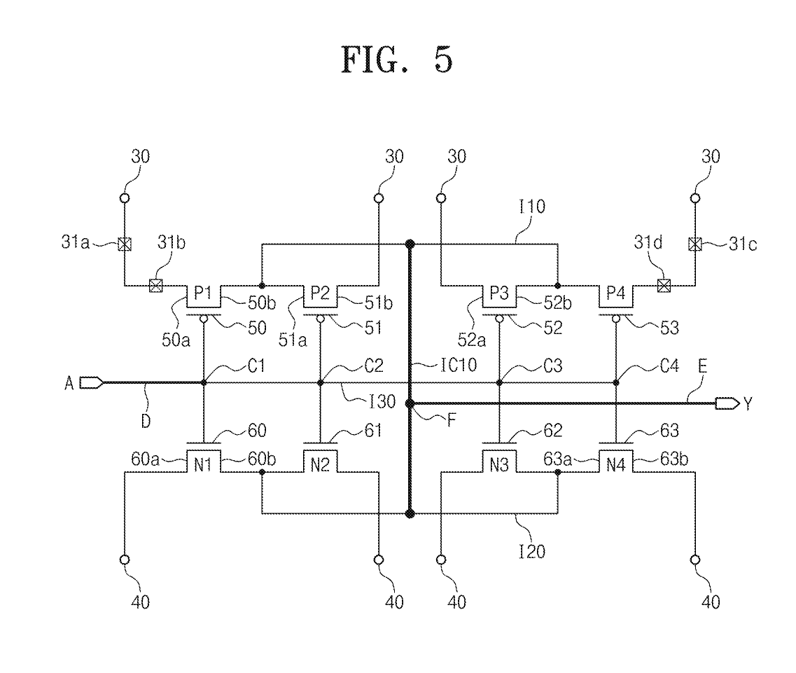

FIG. 5 is a circuit diagram illustrating an example of forming an ECO cell using the decoupling capacitor circuit in FIG. 4 during an ECO event. In addition to the circuit configuration in FIG. 4, FIG. 5 shows that an interconnection metal line pattern IC10 is disposed to electrically connect a first interconnection line 110 and a second interconnection line 120 during an upper metal process.

That is, once a spare gate cell existing in the type of a decoupling capacitor is selected as an ECO cell, the interconnection metal line pattern IC10 is formed for a circuit constituting a decoupling capacitor. Thus, the spare gate cell existing in the form of the decoupling capacitor changes into an ECO cell having an inverter function due to the interconnection metal line pattern IC10.

In FIG. 5, an input A applying an electrical signal to converters C1, C2, C3, and C4 through a line D refers to an input of an inverter circuit, and an output Y receiving the electrical signal from the interconnection metal line pattern IC10 through a line E refers to an output of the inverter circuit. When a spare gate cell changes into an ECO cell due to formation of the interconnection metal line pattern IC10 and pintext adding for an inverter circuit is performed, the input A and the output Y function as a signal input terminal and a signal output terminal of the inverter circuit, respectively.

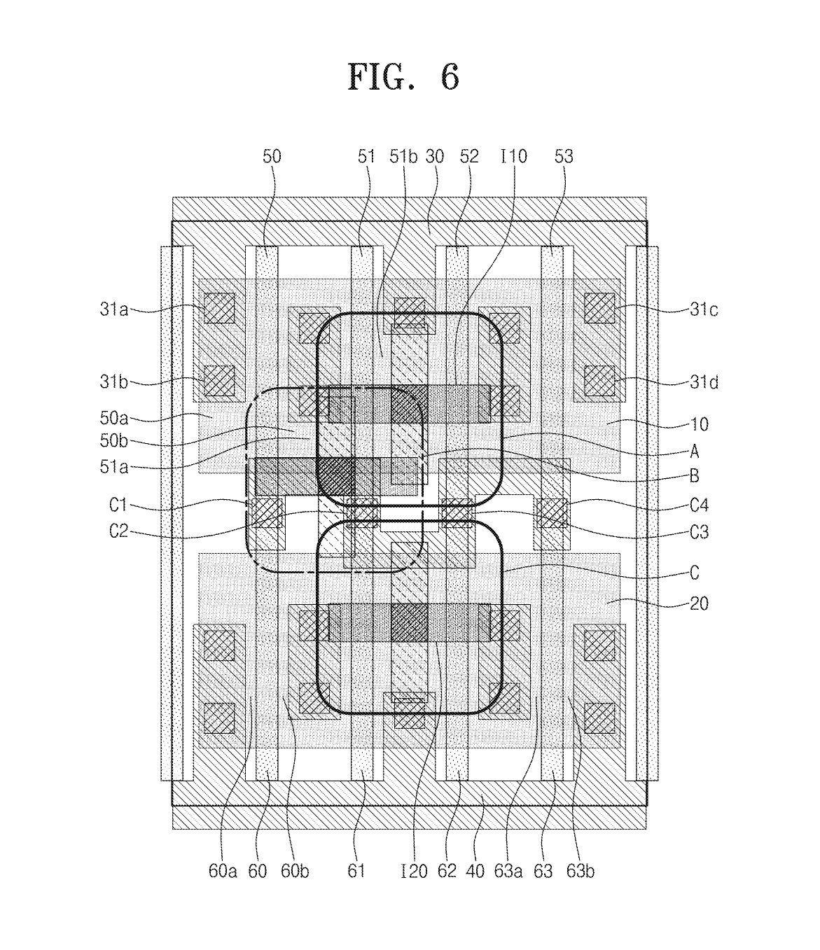

FIG. 6 is a diagram illustrating a layout of the decoupling capacitor circuit according to FIG. 4. As illustrated, a decoupling capacitor-type spare gate cell capable of changing into an inverter circuit includes a first conductivity-type active region 10 and a second conductivity-type active region 20.

The first conductivity-type active region 10 may be formed as a region doped with P-type ions at a given concentration in an N-well formed at a portion of a P-type substrate to form a source/drain region of a PMOS transistor.

The second conductivity-type active region 20 may be formed as a region doped with N-type ions at a given concentration at a portion of the P-type substrate to form a source/drain region of an NMOS transistor.

The first group transistors P1, P2, P3, and P4 in FIG. 4 are disposed in the first conductivity-type active region 10, and the second group transistors N1, N2, N3, and N4 in FIG. 4 are disposed in the second conductivity-type active region 20.

In FIG. 6, polysilicon gate patterns 50, 51, 52, and 53 belonging to a first polysilicon gate region are disposed to correspond to gates of the first group transistors P1, P2, P3, and P4, respectively. Polysilicon gate patterns 60, 61, 62, and 63 belonging to a second polysilicon gate region are disposed to correspond to gates of the second group transistors N1, N2, N3, and N4, respectively.

For example, a source 50a of the PMOS transistor P1 in FIG. 4 corresponds to a P-type doped region 50a in which metal power contacts 31a and 31b in FIG. 6 are formed, the drain 50b of the PMOS transistor P1 corresponds to a P-type doped region 50b in FIG. 6, and a gate 50 of the PMOS transistor P1 corresponds to the polysilicon gate pattern 50 in FIG. 6. For example, the source 51a of the PMOS transistor P2 corresponds to a P-type doped region 51a in FIG. 6, a drain 51b of the PMOS transistor P2 corresponds to a P-type doped region 51b in FIG. 6, and a gate 51 of the PMOS transistor P2 corresponds to the polysilicon gate pattern 51 in FIG. 6. The drain 50b of the PMOS transistor P1 and the source 51a of the PMOS transistor P2 are formed using a common active region.

Gate contacts C1, C2, C3, and C4 in FIG. 6 correspond to the contacts C1, C2, C3, and C4 in FIG. 4, respectively. A first interconnection line 110 in FIG. 6 corresponds to the first interconnection line 110 in FIG. 4, and a second interconnection line 120 in FIG. 6 corresponds to the second interconnection line 120 in FIG. 4. A metal line 30 may be a power line to which a power supply voltage VDD is applied during change into an ECO cell, and a metal line 40 may be a power line to which a ground voltage VSS is applied during change into the ECO cell. In detail, the metal line 30 is connected to the source 50a of the PMOS transistor P1 through the metal power contacts 31a and 31b, the drain 51b of the PMOS transistor P2, a drain 52a of the PMOS transistor P3, and a drain of the PMOS transistor P4 through metal power contacts 31c and 31d. The metal line 40 is connected to a drain 60a of the NMOS transistor N1, a source of the NMOS transistor N2, a source of the NMOS transistor N3, and a source 63b of the NMOS transistor N4.

A spare gate cell having a structure shown in FIG. 6 may be in the form of a decoupling capacitor when or before a metal-1 process is completed.

After an ECO, parts A, B., and C shown in FIG. 6 are changed to constitute an ECO cell having an inverter function.

That is, the part A and the part C are electrically connected to each other through a metal interconnection formed in a process of metal-1 or higher level, and pintext adding is performed on the part B to provide an input terminal of an inverter. The pintext adding refers to a work performed in software. During change into an ECO cell, the pintext adding may be performed to provide an electrical signal. Thus, a pintext-added pin functions as an input pin or an output pin.

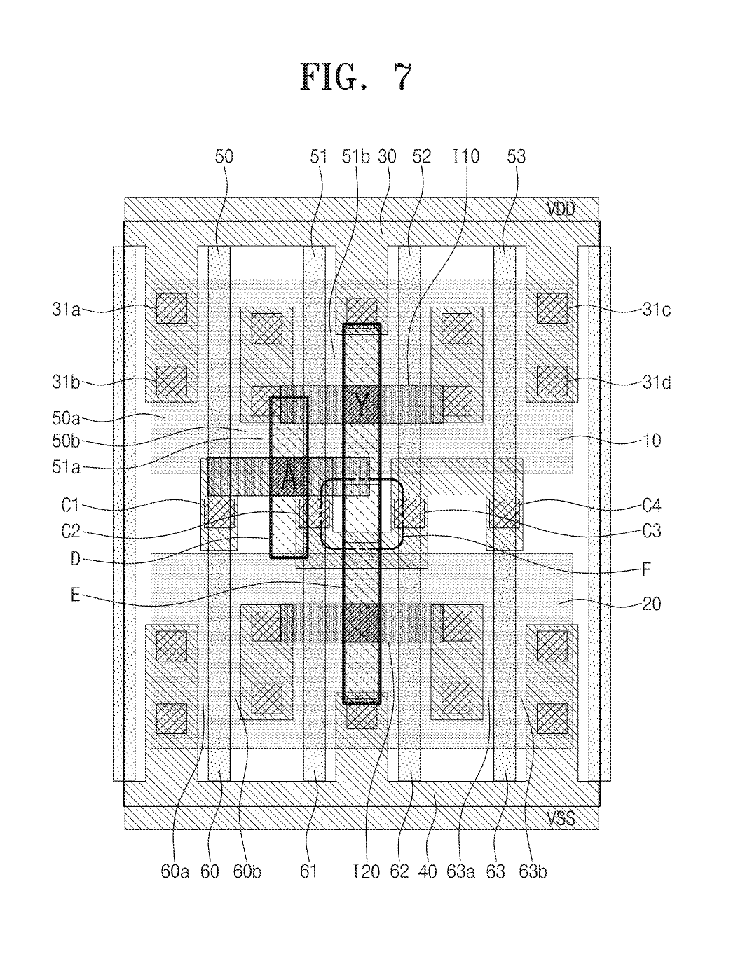

FIG. 7 is a diagram illustrating a layout of an ECO cell using the decoupling capacitor circuit according to FIG. 5. Referring to FIG. 7, the interconnection metal line IC10 in FIG. 5 is disposed in a part F. Accordingly, a spare gate cell existing in the form of a decoupling capacitor as shown in FIG. 6 changes into an ECO cell having an inverter function due to formation of the interconnection metal line pattern IC10 in FIG. 7. In the part F, the interconnection metal line pattern IC10 is formed at an upper metal layer disposed at a higher level than a metal-1 layer.

In FIG. 7, the input A shown in a region D by the pintext adding indicates an input terminal of an inverter, and the output Y shown in a region E by the pintext adding indicates an output of the inverter.

As a result, in example embodiments, decoupling capacitors are manufactured as spare gate cells for an ECO cell as shown in FIG. 6, and an ECO cell is formed using the manufactured decoupling capacitor when an ECO event occurs even after a metal-1 process is performed. The formed ECO cell is rerouted to functional cells to change, revise or add a function or timing of the functional cells.

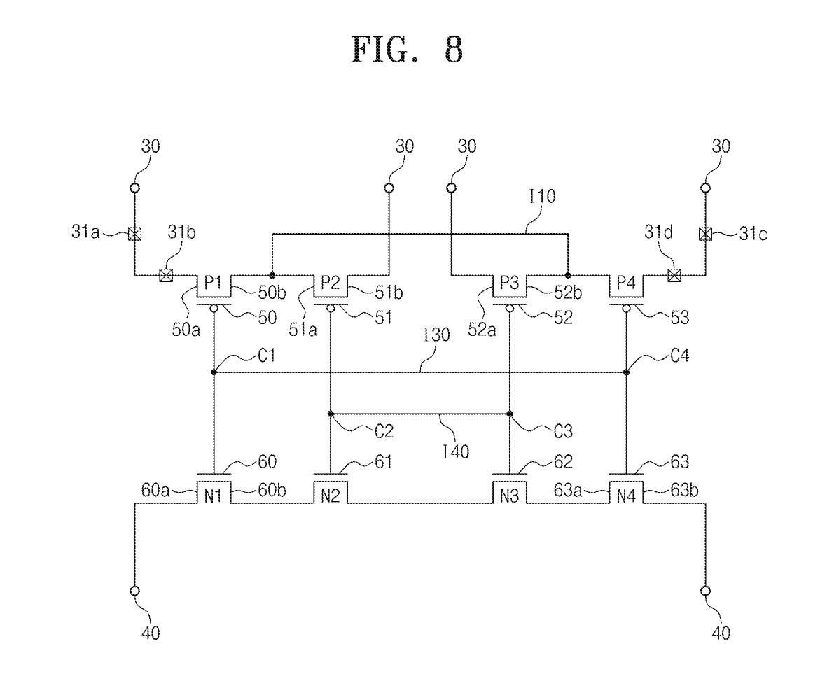

FIG. 8 is a circuit diagram illustrating a decoupling capacitor circuit capable of changing into a NAND circuit, according to example embodiments. As illustrated, the decoupling capacitor circuit includes the four PMOS transistors P1, P2, P3, and P4 and the four NMOS transistors N1, N2, N3, and N4. For brevity of description, the four PMOS transistors P1, P2, P3, and P4 will be referred to as first group transistors, and the four NMOS transistors N1, N2, N3, and N4 will be referred to as second group transistors.

The first interconnection line 110 electrically connects the drain 50b of the first PMOS transistor P1 and the source of the fourth PMOS transistor P4. Because the drain 50 of the first PMOS transistor P1 and the source 51a of the second PMOS transistor P2 may be implemented with a common active region, the first interconnection line 110 also electrically connects the source 51a of the second PMOS transistor P2 and the source 52b of the third PMOS transistor P3.

The source 60b of the first NMOS transistor N1 and the drain of the second NMOS transistor N2 may be implemented with a common active region. The source of the second NMOS transistor N2 and the source of the third NMOS transistor N3 may be implemented with a common active region. Unlike the case in FIG. 4, the second interconnection line 120 shown in FIG. 4 does not exist in FIG. 8.

The third interconnection line 130 electrically connects gates 50 and 53 of the two PMOS transistors P1 and P4 to gates 60 and 63 of the two NMOS transistors N1 and N4.

A fourth interconnection line 140 electrically connects gates 51 and 52 of the two PMOS transistors P2 and P3 to gates 61 and 62 of the NMOS transistors N2 and N3.

Because a spare gate cell shown in FIG. 8 is formed in the type of a decoupling capacitor to implement an ECO cell, a power consumption issue caused by short-circuit current does not occur even when a power supply voltage or a ground voltage is not applied to a gate of each of the eight MOS transistors P1, P2, P3, P4, N1, N2, N3, and N4. As a result, the spare gate cell for the ECO cell exists in the form of the decoupling capacitor before an ECO and may perform a function of a NAND circuit after the ECO.

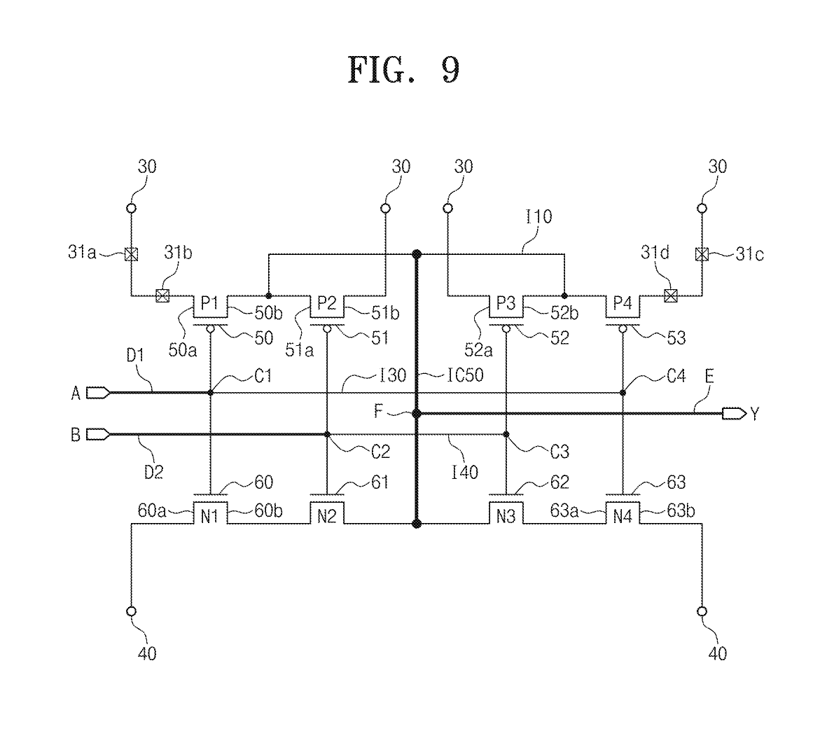

FIG. 9 is a circuit diagram illustrating an example of forming an ECO cell for a NAND function using the decoupling capacitor circuit in FIG. 8 during an ECO event. In addition to the circuit configuration in FIG. 8, FIG. 9 shows that an interconnection metal line pattern 1050 is formed to electrically connect the first interconnection line 110 and the source of the second NMOS transistor N2 during an upper metal process.

That is, once a spare gate cell existing in the type of a decoupling capacitor is selected as an ECO cell, the interconnection metal line pattern 1050 is formed for a circuit constituting a decoupling capacitor. Thus, the spare gate cell existing in the form of the decoupling capacitor changes into an ECO cell having an inverter function due to the interconnection metal line pattern IC50.

In FIG. 9, an input A applying an electrical signal to the contact C1 through a line D1 refers to an input of a NAND circuit, an input B applying an electrical signal to the contact C2 through a line D2 refers to a second input of the NAND circuit, and an output Y receiving the electrical signal from the interconnection metal line pattern IC50 through the line E refers to an output of the inverter circuit. When a spare gate cell changes into an ECO cell due to formation of the interconnection metal line pattern IC50 and pintext adding for an inverter circuit is performed, the inputs A and B and the output Y function as signal input terminals and a signal output terminal of the NAND circuit, respectively.

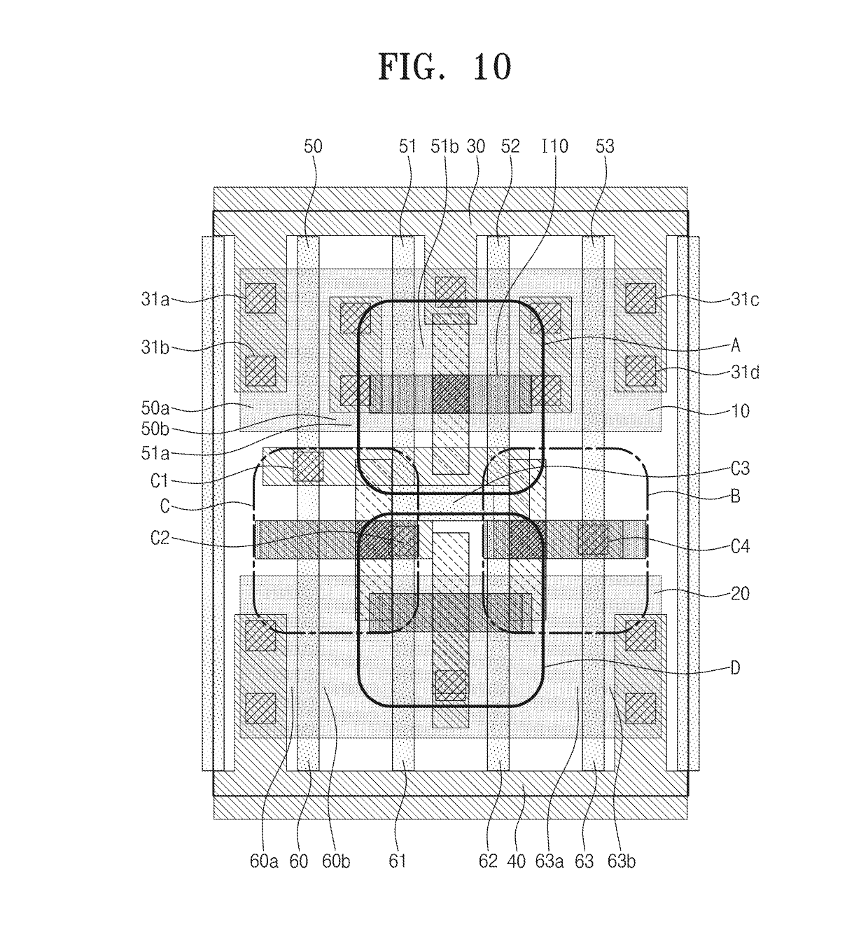

FIG. 10 is a diagram illustrating a layout of the decoupling capacitor circuit according to FIG. 8. As illustrated, a decoupling capacitor-type spare gate cell capable of changing into an inverter circuit includes the first conductivity-type active region 10 and the second conductivity-type active region 20.

The first conductivity-type active region 10 may be formed as a region doped with P-type ions at a given concentration in an N-well formed at a portion of a P-type substrate to form a source/drain region of a PMOS transistor.

The second conductivity-type active region 20 may be formed as a region doped with N-type ions at a given concentration at a portion of the P-type substrate to form a source/drain region of an NMOS transistor.

The first group transistors P1, P2, P3, and P4 in FIG. 8 are disposed in the first conductivity-type active region 10, and the second group transistors N1, N2, N3, and N4 in FIG. 8 are disposed in the second conductivity-type active region 20.

In FIG. 10, polysilicon gate patterns 50, 51, 52, and 53 belonging to a first polysilicon gate region are disposed to correspond to the gates 50, 51, 52, and 53 of the first group transistors P1, P2, P3, and P4, respectively. Polysilicon gate patterns 60, 61, 62, and 63 belonging to a second polysilicon gate region are disposed to correspond to the gates 60, 61, 62, and 63 of the second group transistors N1, N2, N3, and N4, respectively.

For example, the source 50a of the PMOS transistor P1 in FIG. 8 corresponds to a P-type doped region 50a in which the metal power contacts 31a and 31b in FIG. 10 are formed, the drain 50b of the PMOS transistor P1 corresponds to a P-type doped region 50b in FIG. 10, and the gate 50 of the PMOS transistor P1 corresponds to the polysilicon gate pattern 50 in FIG. 10. For example, the source 51a of the PMOS transistor P2 corresponds to a P-type doped region 51a in FIG. 10, the drain 51b of the PMOS transistor P2 corresponds to a P-type doped region 51b in FIG. 10, and the gate 51 of the PMOS transistor P2 corresponds to the polysilicon gate pattern 51 in FIG. 10. The drain 50b of the PMOS transistor P1 and the source 51a of the PMOS transistor P2 are formed using a common active region.

Similarly, drains/sources of the second group transistors N1, N2, N3, and N4 are also formed using a common active region.

Gate contacts C1, C2, C3, and C4 in FIG. 10 correspond to the contacts C1, C2, C3, and C4 in FIG. 8, respectively. The first interconnection line 110 in FIG. 10 corresponds to the first interconnection line 110 in FIG. 8.

A spare gate cell having a structure shown in FIG. 10 may be in the form of a decoupling capacitor when or before a metal-1 process is completed.

After an ECO, parts A, B., C and D shown in FIG. 10 are changed to constitute an ECO cell having a NAND function.

That is, the part A and the part D are electrically connected to each other through a metal interconnection formed in a process of metal-1 or higher level, and pintext adding is performed on the parts B and C to provide input terminals of a NAND circuit. The pintext adding refers to a work performed in software. During change into an ECO cell, the pintext adding may be performed to provide an electrical signal. Thus, a pintext-added pin functions as an input pin or an output pin.

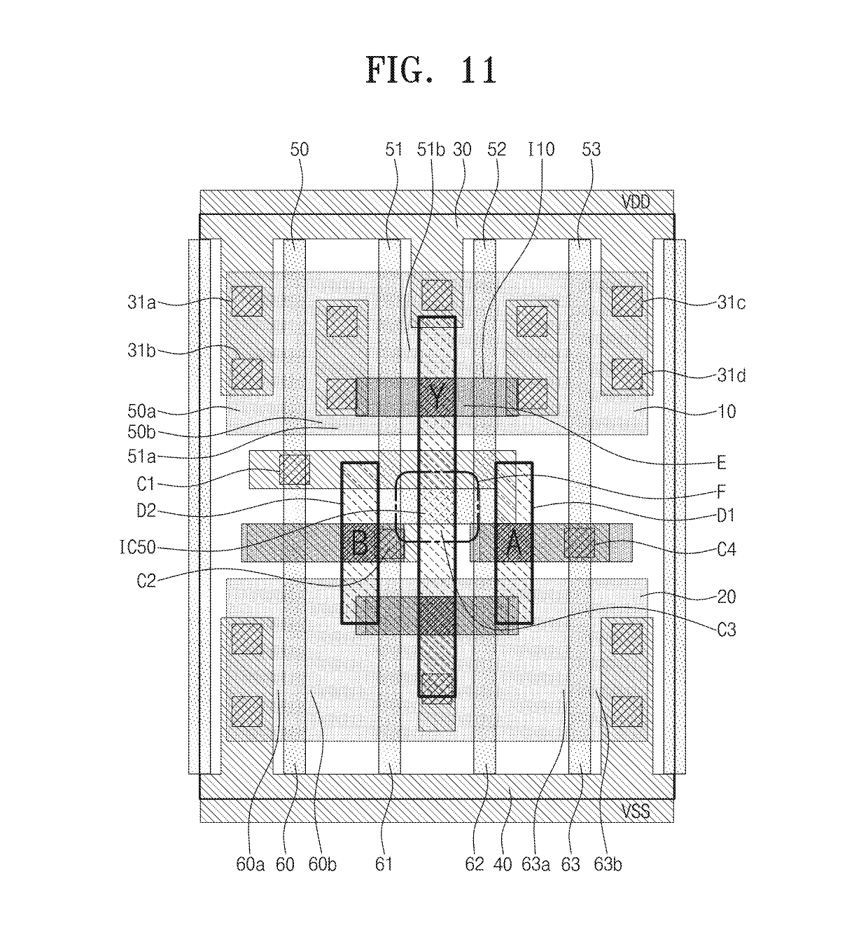

FIG. 11 is a diagram illustrating a layout of an ECO cell for a NAND function using the decoupling capacitor circuit according to FIG. 9. Referring to FIG. 11, the interconnection metal line pattern IC50 in FIG. 9 is formed at a part F. As a result, a spare gate cell existing in the form of a decoupling capacitor as shown in FIG. 10 changes into an ECO cell having a NAND function due to formation of an interconnection metal line pattern IC50 in FIG. 11. At the part F, the interconnection metal line pattern IC50 is formed at an upper metal layer higher than a metal-1 layer.

In FIG. 11, the input A shown in a region D1 by pintext adding indicates a first input terminal of a NAND gate, the input B shown in a region D2 by the pintext adding indicates a second input terminal of the NAND gate, and the output Y shown in a region E by the pintext adding indicates an output terminal of the NAND gate.

As a result, in example embodiments, decoupling capacitors are manufactured as spare gate cells for ECO cells as shown in FIG. 10, and an ECO cell is formed using the manufactured decoupling capacitor when an ECO event occurs even after a metal-1 process is performed. The formed ECO cell is rerouted to functional cells to change, revise or add a function or timing of the functional cells.

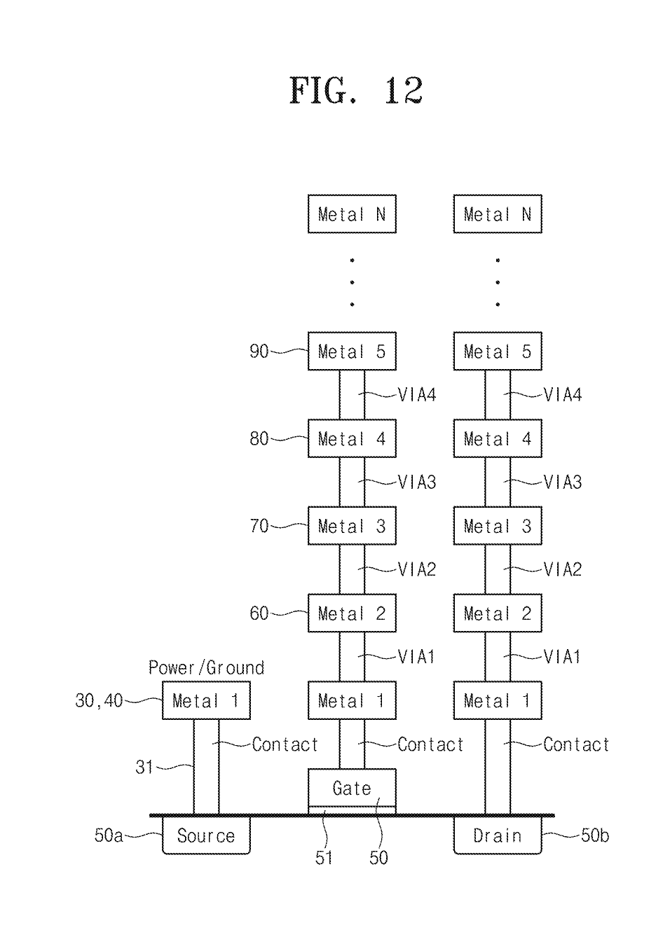

FIG. 12 is a diagram illustrating a vertical structure of a MOS transistor, according to example embodiments. In FIG. 12, a structure of a MOS transistor having the source 50a, the drain 50b, and the gate 50 is shown. When the source 50a and the drain 50b of the MOS transistor are electrically connected to each other, a decoupling capacitor is formed. That is, the gate 50 above a gate insulating layer 51 acts as a top plate and the source 50a and the drain 50b below the gate insulating layer 51 acts as a bottom plate to form a decoupling capacitor.

In example embodiments, when an ECO event occurs in an upper process higher than a metal-1 process even after performing a current process as the upper process higher than the metal-1 process, an ECO cell for implementing an ECO may be formed in a metal-2 process, a metal-3 process, a metal-4 process or a metal-5 process. That is, for example, when an ECO event occurs after performing the metal-2 process, an ECO cell may be formed in the metal-3 process by using a spare gate cell existing in the type of a decoupling capacitor. For example, when a NAND circuit is in an ECO, the spare gate cell in FIG. 10 changes into an ECO cell in FIG. 11.

In FIG. 12, a metal-5 layer 90 refers to a layer where fifth metal deposition is performed, a metal-4 layer 80 refers to a layer where fourth metal deposition is performed, a metal-3 layer 70 refers to a layer where third metal deposition is performed, and a metal-2 layer 60 refers to a layer where second metal deposition is performed.

Conventionally, because a target layer of a prepared ECO cell has already passed when a process is performed to form a metal-1 layer 30, 40, it may be difficult to form an ECO cell in an upper metal process. However, in example embodiments, because a spare gate cell is formed in the type of a decoupling capacitor, an ECO cell may be formed by forming a metal interconnection even in an upper metal process, as described with reference to FIG. 7 or 11.

In FIG. 12, a reference numeral 31 represents a contact to electrically connect a pattern of the metal-1 layer 30, 40 and the source 50a. The contact 31 may be formed by depositing an interlayer dielectric, selectively etching a portion where the contact is formed, and filling a conductive layer such as silicide or metal. A via contact VIA is a contact to electrically connect between metal layers, and a conductive material such as tungsten or aluminum may be used as a contact material.

A spare gate cell may indicate a single gate. However, in other example embodiments, a plurality of gates may be used to implement a single spare gate cell. Apart from an inverter or NAND gates, another type of gates may be formed to include NOR gates, XOR gates, multiplexer gates, flip-flop gates or buffers.

In example embodiments, an IC may include a large number of electronic devices, cells, and circuits to perform functions according to the request of design specifications.

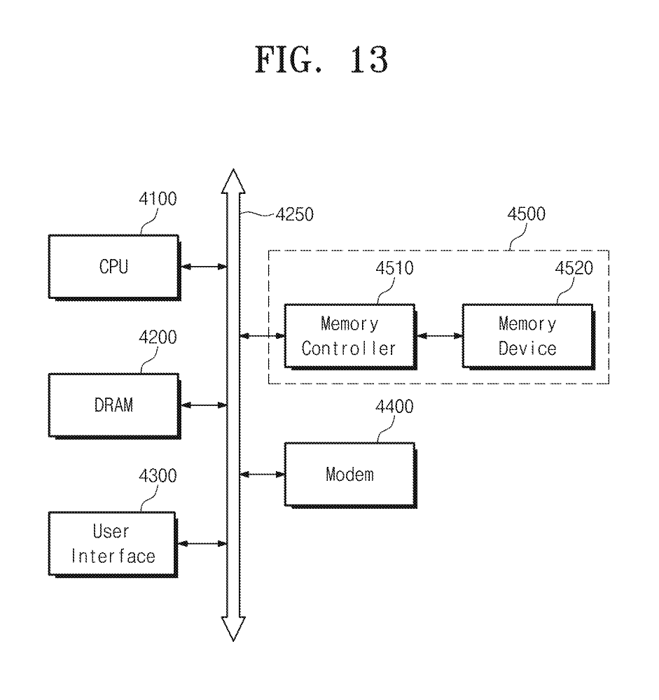

FIG. 13 is a block diagram illustrating an application example applied to a computing device. As illustrated, the computing device includes a memory system 4500 including a memory device 4520 and a memory controller 4510. In example embodiments, the computing device further includes a modem 4400, a central processing unit (CPU) 4100, a dynamic random access memory (DRAM) 4200, and a user interface 4300 that are electrically connected to a system bus 4250. Data processed by the CPU 4100 or externally input data may be stored in the memory system 4500.

The computing device may be applied to a solid state drive (SSD), a camera image sensor, and other application chipsets. In example embodiments, the memory system 4500 may include an SSD. In this case, the computing device may store high-capacity data in the memory system 4500.

In the memory system 4500, the memory controller 4510 may apply a command, an address, data or other control signals to the memory device 4520.

The CPU 4100 functions as a host and controls the overall operation of the computing device.

In the case of the memory system 4500 including the memory device 4520 and the memory controller 4510 in the computing device, an ECO is implemented at an upper metal layer by a spare gate cell. Thus, manufacturing cost of the memory system 4500 may be reduced.

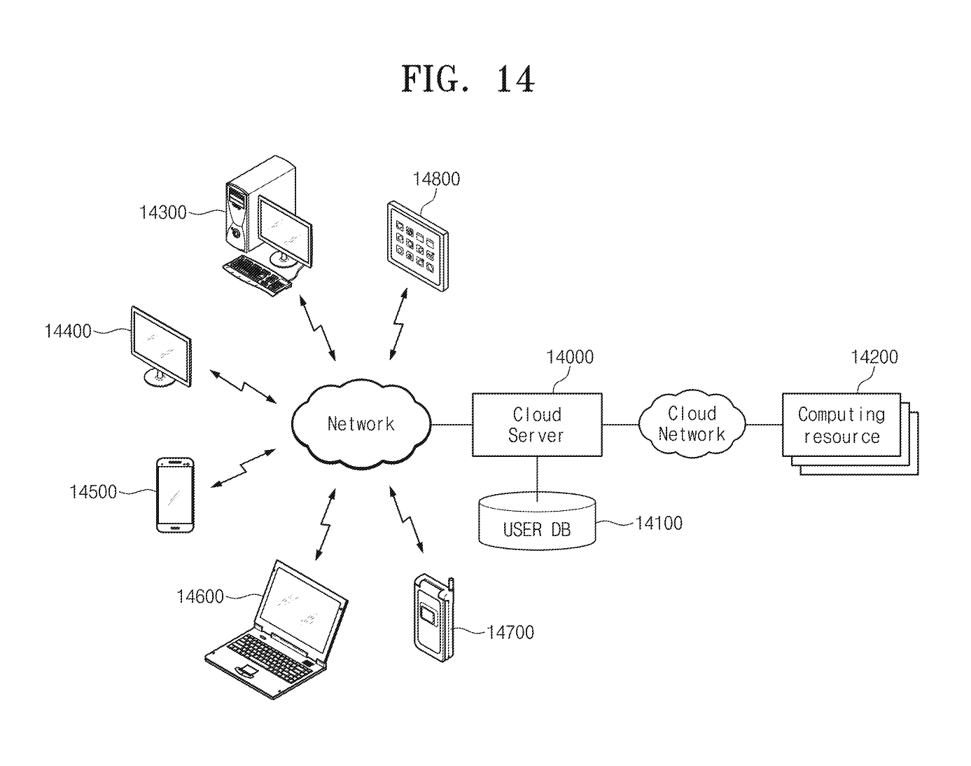

FIG. 14 is a block diagram illustrating an application example applied to a cloud system. As illustrated, the cloud system (or cloud computing system) includes a cloud server 14000, a user DB 14100, a computing resource 14200, and a plurality of user terminals.

The cloud system may provide an on-demand outsourcing service of the computing resource 14200 through an information communication network such as internet according to a request of the user terminal. Under a cloud computing environment, a service provider may integrate computing resources of a data center existing at different physical positions to provide services to users.

A service user does not use computing resources such as an application, a storage, an operating system (OS), and security after mounting the computing resources on each user's terminal but may selectively use services on a virtual space generated by a virtualization technology at a desired point of time.

A service user's terminal is connected to the cloud computing server 14000 through an information communication network including internet and a mobile communication network. Users' terminals may receive a cloud computing service, e.g., a video playback service from the cloud server 14000. In FIG. 14, a desktop PC 14300, a smart TV 14400, a smartphone 14500, a laptop computer 14600, a portable multimedia player (PMP) 14700, and a tablet PC 14800 are shown as examples of the user's terminal. However, the user's terminal is not limited to the above list and may include all electronic devices capable of connecting to internet.

The cloud server 14000 may integrate a plurality of computing resources 14200 distributed to a cloud network and provide the integrated computing resources 14200 to the user's terminal. The computing resources 14200 includes various data services and may include data updated from the user's terminal. The cloud computing sever 14000 integrates video database distributed to various locations through the virtualization technology to provide a service that the user's terminal uses.

When an integrated circuit is manufactured for the cloud server 14000, the user DB 14100, the computing resource 14200 or the plurality of users' terminals, an ECO is implemented even at an upper metal layer by a spare gate cell. Thus, the system manufacturing cost may be reduced.

As described so far, an ECO may be implemented even at an upper metal layer by a spare gate cell.

In addition, the example embodiments may also be implemented through computer-readable code and/or instructions on a medium, e.g., a computer-readable medium, to control at least one processing element to implement any above-described example embodiments. The medium may correspond to any medium or media that may serve as a storage and/or perform transmission of the computer-readable code.

The computer-readable code may be recorded and/or transferred on a medium in a variety of ways, and examples of the medium include recording media, such as magnetic storage media (e.g., ROM, floppy disks, hard disks, etc.) and optical recording media (e.g., compact disc read only memories (CD-ROMs) or digital versatile discs (DVDs)), and transmission media such as Internet transmission media. Thus, the medium may have a structure suitable for storing or carrying a signal or information, such as a device carrying a bitstream according to one or more example embodiments. The medium may also be on a distributed network, so that the computer-readable code is stored and/or transferred on the medium and executed in a distributed fashion. Furthermore, the processing element may include a processor or a computer processor, and the processing element may be distributed and/or included in a single device.

At least one of the components, elements, modules or units represented by a block as illustrated in FIGS. 13 and 14 may be embodied as various numbers of hardware, software and/or firmware structures that execute respective functions described above, according to example embodiments. For example, at least one of these components, elements, modules or units may use a direct circuit structure, such as a memory, a processor, a logic circuit, a look-up table, etc. that may execute the respective functions through controls of one or more microprocessors or other control apparatuses. Also, at least one of these components, elements, modules or units may be embodied by a module, a program, or a part of code that contains one or more executable instructions for performing specified logic functions, and executed by one or more microprocessors or other control apparatuses. Also, at least one of these components, elements, modules or units may further include or may be implemented by a processor such as a central processing unit (CPU) that performs the respective functions, a microprocessor, or the like. Two or more of these components, elements, modules or units may be combined into one single component, element, module or unit performing all operations or functions of the combined two or more components, elements, modules or units. Also, at least part of functions of at least one of these components, elements, modules or units may be performed by another of these components, elements, modules or units. Further, communication between the components, elements, modules or units may be performed through a bus. Functional aspects of the above example embodiments may be implemented in algorithms that execute on one or more processors. Furthermore, the components, elements, modules or units represented by a block or processing steps may employ any number of related art techniques for electronics configuration, signal processing and/or control, data processing and the like.

Although a few example embodiments have been shown and described, it would be appreciated by those skilled in the art that changes may be made in the example embodiments without departing from the principles and spirit of the disclosure, the scope of which is defined in the claims and their equivalents.

What is claimed is:

1. An integrated circuit comprising:
a functional cell; and
a spare gate cell configured to change or add a function of the functional cell in response to an engineering change order (ECO),
wherein the spare gate cell comprises transistors configured as a decoupling capacitor before the ECO, and
wherein the spare gate cell is configured to change into an ECO cell comprising an interconnection metal line pattern disposed in the decoupling capacitor after the ECO.

2. The integrated circuit as set forth in claim 1, wherein the transistors comprise:
first group transistors having a first conductivity type; and
second group transistors having a second conductivity type, and wherein the spare gate cell further comprises:
a first interconnection line connected to a source or a drain of each of two or more of the first group transistors;
a second interconnection line connected to a source or a drain of each of two or more of the second group transistors; and
a third interconnection line connected to gates of two or more of the first group transistors and the second group transistors.

3. The integrated circuit as set forth in claim 2, wherein the ECO cell further comprises:
an input connected to the third interconnection line; and
an output connected to the interconnection metal line pattern.

4. The integrated circuit as set forth in claim 1, wherein the interconnection metal line pattern is formed in an upper process higher than a metal-1 process, in response to the ECO.

5. The integrated circuit as set forth in claim 4, wherein the upper process comprises a metal-2 process.

6. The integrated circuit as set forth in claim 4, wherein the upper process comprises a metal-3 process.

7. The integrated circuit as set forth in claim 1, wherein the ECO cell is configured as an inverter circuit.

8. The integrated circuit as set forth in claim 1, wherein the ECO cell is configured as a NAND circuit.

9. The integrated circuit as set forth in claim 1, wherein the ECO cell is configured as a NOR circuit.

10. The integrated circuit as set forth in claim 1, wherein the transistors comprise eight complementary metal oxide semiconductor transistors.

11. A method for forming a spare cell structure of an integrated circuit, the method comprising:
forming, in the integrated circuit, a spare gate cell as a decoupling capacitor before an engineering change order (ECO); and
forming an interconnection metal line pattern in the decoupling capacitor after the ECO event to change the spare gate cell into an ECO cell.

12. The method as set forth in claim 11, further comprising forming a functional cell in the integrated circuit.

13. The method as set forth in claim 11, wherein the spare gate cell comprises:
first group transistors having a first conductivity type;
second group transistors having a second conductivity type;
a first interconnection line connected to a source or a drain of each of two or more of the first group transistors;
a second interconnection line connected to a source or a drain of each of two or more of the second group transistors; and
a third interconnection line connected to gates of two or more of the first group transistors and the second group transistors.

14. The method as set forth in claim 11, wherein the interconnection metal line pattern is formed in an upper process higher than a metal-1 process, in response to the ECO.

15. The method as set forth in claim 11, wherein the ECO cell is configured as one among an inverter circuit, a NAND circuit, and a NOR circuit.

16. An integrated circuit comprising:
a functional cell; and
a spare gate cell configured to change or add a function of the functional cell in response to an engineering change order (ECO),
wherein before the ECO, the spare gate cell comprises:
first transistors having a first conductivity type;
second transistors having a second conductivity type;
a first interconnection line connected to a source or a drain of each of two or more of the first transistors;
a second interconnection line connected to a source or a drain of each of two or more of the second transistors; and
a third interconnection line connected to gates of the first group transistors and the second group transistors, and
wherein after the ECO, the spare gate cell further comprises a fourth interconnection line connected to the first interconnection line and the second interconnection line.

17. The integrated circuit as set forth in claim 16, wherein after the ECO, the spare gate cell further comprises:
an input connected to the third interconnection line; and
an output connected to the fourth interconnection line.

18. The integrated circuit as set forth in claim 16, wherein the spare gate cell further comprises the fourth interconnection line after the ECO and after forming a metal layer over the first transistors and second transistors.

19. The integrated circuit as set forth in claim 16, wherein the first transistors comprise a first PMOS transistor, a second PMOS transistor comprising a source connected to a drain of the first PMOS transistor, a third PMOS transistor comprising a source connected to the source of the second PMOS transistor via the first interconnection line, and a fourth PMOS transistor comprising a source connected to the source of the third PMOS transistor, and
wherein the second transistors comprise a first NMOS transistor, a second NMOS transistor comprising a drain connected to a source of the first NMOS transistor, a third NMOS transistor comprising a drain connected to the drain of the second NMOS transistor via the second interconnection line, and a fourth NMOS transistor comprising a drain connected to the drain of the third NMOS transistor.

20. The integrated circuit as set forth in claim 16, wherein the first transistors comprise a first PMOS transistor, a second PMOS transistor comprising a source connected to a drain of the first PMOS transistor, a third PMOS transistor comprising a source connected to the source of the second PMOS transistor via the first interconnection line, and a fourth PMOS transistor comprising a source connected to the source of the third PMOS transistor,
wherein the second transistors comprise a first NMOS transistor, a second NMOS transistor comprising a drain connected to a source of the first NMOS transistor, a third NMOS transistor comprising a source connected to a source of the second NMOS transistor via the second interconnection line, and a fourth NMOS transistor comprising a drain connected to the drain of the third NMOS transistor, and
wherein the third interconnection line comprises a first line connected to gates of the first PMOS transistor, the first NMOS transistor, the fourth PMOS transistor, and the fourth NMOS transistor, and a second line connected to the second PMOS transistor, the second NMOS transistor, the third PMOS transistor, and the third NMOS transistor.
